(19) United States
(12) Patent Application Publication
(10) Pub. No.: US 2012/0246927 A1
(43) Pub. Date: Oct. 4, 2012

(54) SUCTION NOZZLE, MOUNTING APPARATUS, METHOD FOR MOUNTING ELECTRONIC COMPONENTS, AND METHOD FOR MANUFACTURING COMPONENT-MOUNTED SUBSTRATES

(75) Inventor: Tetsuya Kano, Saitama (JP)

(73) Assignee: SONY CORPORATION, Tokyo (JP)

(21) Appl. No.: 13/414,401

(22) Filed: Mar. 7, 2012

(30) Foreign Application Priority Data
Mar. 28, 2011 (JP) 2011-070558

(51) Int. Cl. H05K 3/30; H05K 13/04

(52) U.S. Cl. 29/832; 29/743; 29/741; 29/428

(57) ABSTRACT

A suction nozzle sucking a first electronic component that is mounted on a substrate and has first and second electrodes includes a first sucking area with an opening formed in an area corresponding to the first electrode and a second sucking area with an opening formed in an area corresponding to the second electrode.

### CROSS REFERENCES TO RELATED APPLICATIONS

The present application claims priority to Japanese Priority Patent Application JP 2011-070558 filed in the Japan Patent Office on Mar. 28, 2011, the entire content of which is hereby incorporated by reference.

### BACKGROUND

The present application relates to a technology including a suction nozzle for sucking an electronic component when mounting electronic components on a substrate and a mounting apparatus including this suction nozzle.

In the related art, various mounting apparatus for mounting resistors, capacitors and other electronic components on substrates are disclosed (see Japanese Unexamined Patent Application Publication No. 2001-77594 (Paragraphs [0016]-[0030] and FIG. 2) and Japanese Unexamined Patent Application Publication No. 2003-078290 (Paragraphs [0014]-[0020] and FIGS. 1-3), for example). In these mounting apparatus, electronic components arranged in a supply unit are sucked by suction nozzles. The suction nozzles having sucked the electronic components are moved to positions above a substrate and are lowered to mount the electronic components on the substrate.

The mounting apparatus should mount the electronic components accurately on the substrate. For this purpose, in the mounting apparatus, a technology is typically adopted to capture images of the suction nozzles having sucked the electronic components using an imaging device and to recognize the sucked state of each electronic component with respect to the suction nozzle on the basis of the image thereof captured by the imaging device.

### SUMMARY

In recent years, there is an increasing demand for mounting on substrates resistors, capacitors, and other fine electronic components having electrodes. When a suction nozzle is used to suck these fine electronic components, a problem arises that metal particles from the electrodes are accumulated on the tip of the suction nozzle as the tip is repeatedly brought into contact with the electrodes of the electronic components.

The metal particles accumulated on the tip of the nozzle may cause erroneous recognition of the sucked state of an electronic component with respect to the suction nozzle when the sucked state of the electronic component is recognized. For example, the suction nozzle not having sucked an electronic component may be recognized erroneously as having sucked the electronic component. Furthermore, the boundary between the suction nozzle and the electronic component sucked by the suction nozzle may be erroneously recognized.

It is desirable to provide a technology including a suction nozzle capable of suppressing erroneous recognition of the sucked state of an electronic component with respect to the suction nozzle.

A suction nozzle according to an embodiment of the present application has first and second sucking areas and is adapted to suck a first electronic component that is mounted on a substrate and has first and second electrodes.

The first sucking area has an opening formed in an area corresponding to the first electrode.

The second sucking area has an opening formed in an area corresponding to the second electrode.

In this suction nozzle with the first sucking area corresponding to the first electrode and the second sucking area corresponding to the second electrode, it is possible to reduce the surface area of the tip thereof to be brought into contact with the first and second electrodes. Consequently, it is possible to suppress the accumulation of metal particles from the electrodes on the tip of the suction nozzle and thus suppress erroneous recognition of the sucked state of the first electronic component with respect to the suction nozzle.

The suction nozzle described above may have a recessed area formed between the first and second sucking areas.

For the suction nozzle described above, the first electronic component may have a projection provided between the first and second electrodes.

In this case, the recessed area may have a recess formed in an area corresponding to the projection.

The first electronic component may have a projection between the first and second electrodes. When the first electronic component has such a projection, this projection is brought into contact at a single point with an area between the first and second sucking areas of the nozzle and may cause problems such as the rotation of the first electronic component. On the other hand, the suction nozzle in the present embodiment has the recessed area formed in an area corresponding to the projection of the first electronic component, so that the projection of the first electronic component sucked by the suction nozzle fits in the recessed area of the suction nozzle. This can prevent the rotation of the first electronic component with respect to the suction nozzle.

The suction nozzle described above may be used commonly to mount the first electronic component and to mount a second electronic component having a projection and larger in size than the first electronic component.

In this case, a total area formed of the first and second sucking areas and recessed area of the sucking nozzle may receive the projection of the second electronic component.

In this embodiment, the total area formed of the first and second sucking areas and the recessed area receive the projection of the second electronic component that is larger in size than the first electronic component. When the suction nozzle sucks the second electronic component, the total area formed of the first and second sucking areas and the recessed area can receive the projection of the second electronic component and thus prevent the rotation of the second electronic component with respect to the suction nozzle.

For the suction nozzle described above, the first electronic component may have the first electrode disposed at one end thereof, the second electrode disposed at another end thereof, and an electronic component body that is thinner than the first and second electrodes.

In this case, air leakage and other related problems can also be mitigated.

A mounting apparatus according to another embodiment of the present application includes a head and a suction nozzle.

The suction nozzle is attached to the head and has first and second sucking areas for sucking an electronic component that is mounted on a substrate and has first and second electrodes.

The first sucking area has an opening formed in an area corresponding to the first electrode.

The second sucking area has an opening formed in an area corresponding to the second electrode.

A method for mounting electronic components according to another embodiment of the present application includes sucking an electronic component having first and second electrodes using a suction nozzle having first and second sucking areas. The first sucking area has an opening formed in an area corresponding to the first electrode and the second sucking area has an opening formed in an area corresponding to the second electrode.

The suction nozzle having sucked the electronic component is moved to a position above the substrate and mounts the electronic component on the substrate.

A method for manufacturing component-mounted substrates according to another embodiment of the present application includes sucking an electronic component having first and second electrodes using a suction nozzle having first and second sucking areas. The first sucking area has an opening formed in an area corresponding to the first electrode and the second sucking area has an opening formed in an area corresponding to the second electrode.

The suction nozzle having sucked the electronic component is moved to a position above a substrate and mounts the electronic component on the substrate.

As described above, the embodiments of the present application can provide a technology including a suction nozzle capable of suppressing erroneous recognition of the sucked state of the electronic component with respect to the suction nozzle.

Additional features and advantages are described herein, and will be apparent from the following Detailed Description and the figures.

### BRIEF DESCRIPTION OF THE FIGURES

FIG. 1 is a front view showing a mounting apparatus according to an embodiment of the present application;

FIG. 2 is a plan view of the mounting apparatus shown in FIG. 1;

FIG. 3 is a side view showing the tip of a suction nozzle;

FIGS. 4A and 4B are enlarged views showing the tip of the suction nozzle;

FIGS. 5A and 5B show an exemplary electronic component to be sucked and mounted by the suction nozzle;

FIGS. 6A and 6B show an electronic component sucked by the tip of the suction nozzle;

FIGS. 7A and 7B show an electronic component sucked by a suction nozzle according to a comparative example;

FIGS. 8A and 8B show an exemplary electronic component having a main body thinner than the first and second electrodes;

FIG. 9 is a side view showing the electronic component shown in FIGS. 8A and 8B sucked by the suction nozzle according to the present embodiment;

FIG. 10 is a side view showing the electronic component shown in FIGS. 8A and 8B sucked by the suction nozzle according to the comparative example;

FIGS. 11A and 11B show the tip of a suction nozzle according to another embodiment of the present application;

FIGS. 12A and 12B show an exemplary electronic component to be sucked and mounted by the suction nozzle shown in FIGS. 11A and 11B;

FIGS. 13A and 13B show the electronic component shown in FIGS. 12A and 12B sucked by the suction nozzle shown in FIGS. 11A and 11B;

FIGS. 14A and 14B show an exemplary second electronic component; and

FIGS. 15A and 15B show the exemplary second electronic component sucked by the suction nozzle shown in FIGS. 11A and 11B.

### DETAILED DESCRIPTION

Embodiments of the present application will now be described with reference to the drawings.

### Embodiment

### Configuration of Mounting Apparatus and Configuration of Each Unit

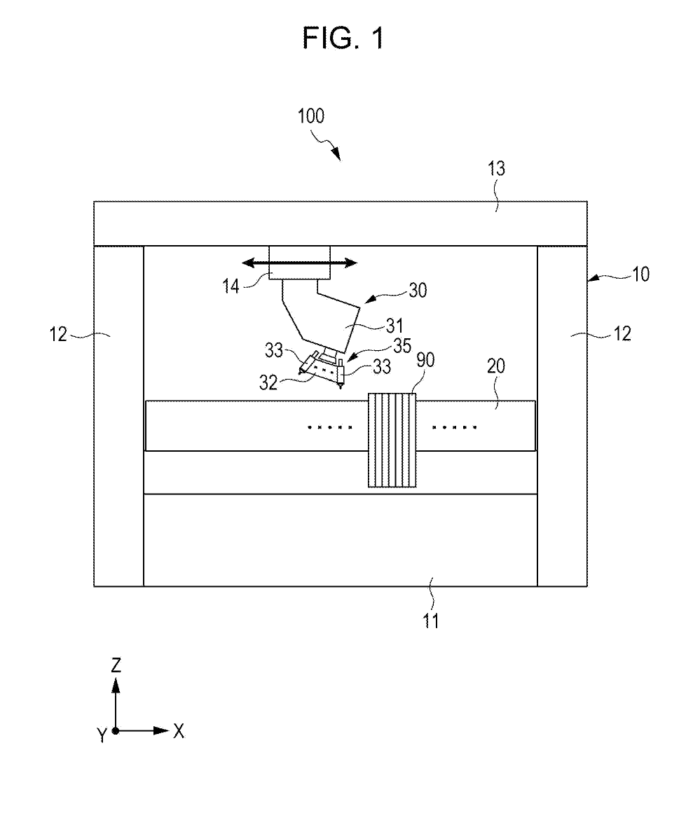

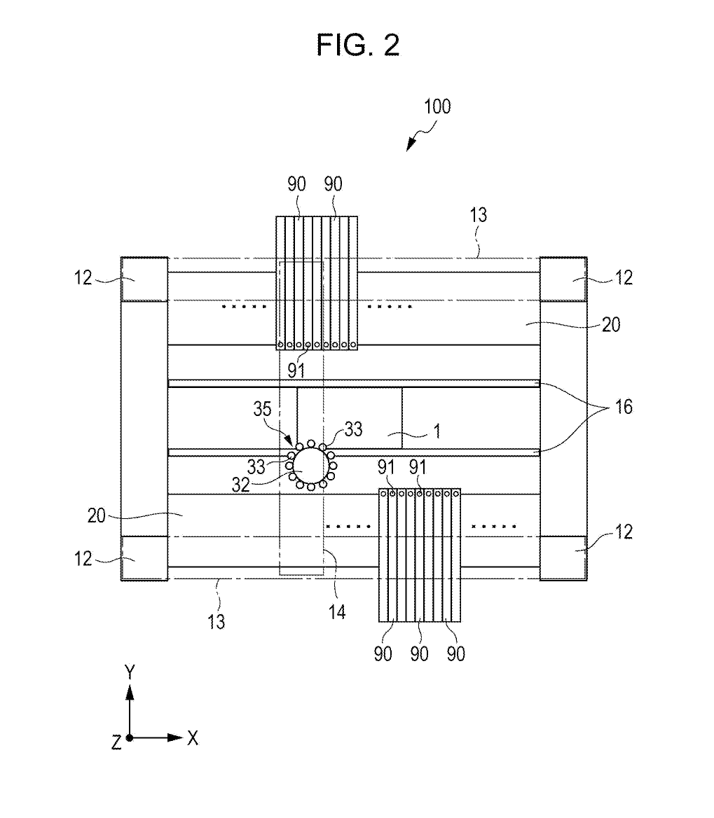

FIG. 1 is a front view showing a mounting apparatus 100 according to an embodiment of the present application. FIG. 2 is a plan view of the mounting apparatus 100 shown in FIG. 1.

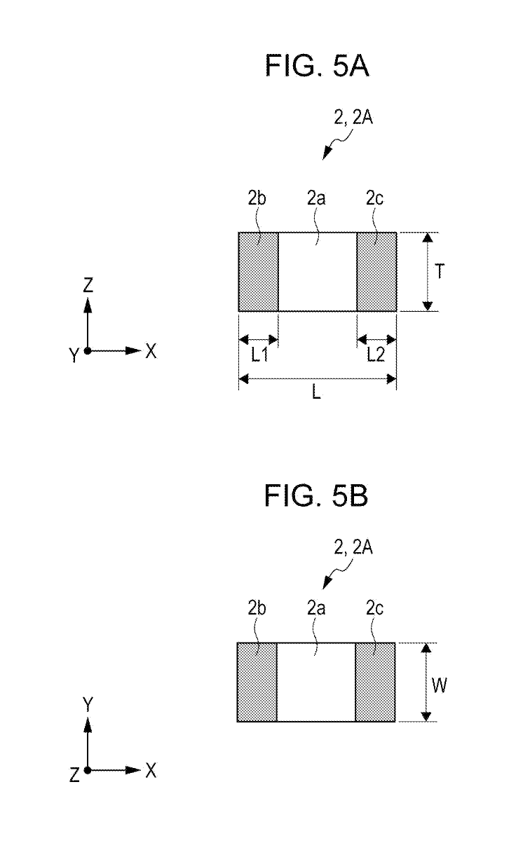

As shown in these drawings, the mounting apparatus 100 includes a frame 10, a conveyor 16 for conveying substrates 1, and tape feeder mounting units 20 disposed on both sides of the conveyor 16 and carrying tape feeders 90 for supplying electronic components 2 (see FIGS. 5A and 5B). The mounting apparatus 100 further includes a mounting mechanism 30 for sucking and mounting the electronic components 2 supplied from the tape feeders 90 on the substrates 1.

Although not shown in the drawings, the mounting apparatus 100 also includes a control unit such as a CPU (central processing unit) for centralized control of the units of the mounting apparatus 100. The mounting apparatus 100 further includes a nonvolatile memory storing various programs for control operations by the control unit and a volatile memory used as the work space by the control unit.

The frame 10 has a base 11 disposed at the bottom thereof and a plurality of columns 12 secured to the base 11. Two X beams 13, for example, extend along the X axis and bridge between the tops of the columns 12. A Y beam 14 extending along the Y axis bridges between the two X beams 13 and has the mounting mechanism 30 disposed thereon. In FIG. 2, for clarity of the drawing, the X beams 13 and Y beam 14 located on the viewer's side are indicated by dot-dash-lines.

A plurality of tape feeders 90 are arranged along the X axis in the tape feeder mounting units 20. A tape feeder 90 includes a reel for winding thereon a carrier tape containing electronic components 2 and a feeding mechanism for step-feeding the carrier tape. Each carrier tape accommodates a predetermined type of electronic components 2 such as resistors, capacitors, or coils. A supply window 91 for supplying the electronic components 2 is formed at one end of the upper surface of the cassette for each tape feeder 90.

The mounting mechanism 30 includes a carriage 31 held by the Y beam 14 and a head unit 35 disposed below the carriage 31. The head unit 35 has a turret 32 (head) rotatably attached to the carriage 31 and a plurality of suction nozzles 33 attached to the turret 32 at regular intervals in the circumferential direction.

The head unit 35 is movable in the X-Y direction between the points of supply of electronic components 2 (positions of the supply windows 91) and positions above the substrate 1.

The turret 32 is rotatable about a tilted axis. The suction nozzles 33 are rotatably held with respect to the turret 32. The suction nozzles 33 are attached to the turret 32 such that the axis of each suction nozzle 33 is tilted with respect to the axis of rotation of the turret 32. The suction nozzles 33 are held movably along the axis thereof with respect to the turret 32. Driven by a nozzle drive mechanism (not shown), the suction nozzle 33 is rotated about the axis thereof or moved along the axis thereof at a predetermined timing. The suction nozzles 33 are also connected to an air compressor (not shown). In response to the switching between a negative pressure and a positive pressure by the air compressor, the suction nozzle 33 can suck or release the electronic component 2.

Of the plurality of suction nozzles 33, the suction nozzle 33 located at the lowest position (the rightmost suction nozzle 33 in FIGS. 1 and 2) has its axis being vertically oriented. The position of the suction nozzle 33 at which the axis thereof is vertically oriented will be referred to hereinafter as the operation position. The suction nozzle 33 located at the operation position is sequentially changed as the turret 32 rotates. Of the plurality of suction nozzles 33, only the suction nozzle 33 located at the operation position is vertically moved by the nozzle drive mechanism and is switched between the negative pressure and the positive pressure by the air compressor.

The mounting apparatus 100 is equipped with a camera (not shown). The camera has an imaging device such as CCD (charge coupled device) or CMOS (complementary metal oxide semiconductor) which captures images of the sucked states of the electronic components 2 sucked by the suction nozzles 33. This camera is installed so as to move integrally with the mounting mechanism 30, for example, and captures images of the sucked states of the electronic components 2 via an optic system such as a mirror (not shown).

The camera captures an image of the sucked state of an electronic component 2 with respect to the suction nozzle 33 when the suction nozzle 33 having sucked the electronic component 2 is moved to a predetermined position by the rotation of the turret 32. For example, the camera captures an image of the sucked state of an electronic component 2 when the suction nozzle 33 having sucked the electronic component 2 is moved to the highest position (leftmost position in FIGS. 1 and 2) by the rotation of the turret 32. The position at which an image of the suction nozzle 33 having sucked the electronic component 2 is captured will be referred to hereinafter as the imaging position. The images of the sucked states captured by the camera are subjected to image processing by the control unit and are used to determine the sucked states. Once the sucked states are determined, the amount of rotation of the suction nozzle 33 for mounting an electronic component 2 is corrected on the basis of the determined sucked state thereof.

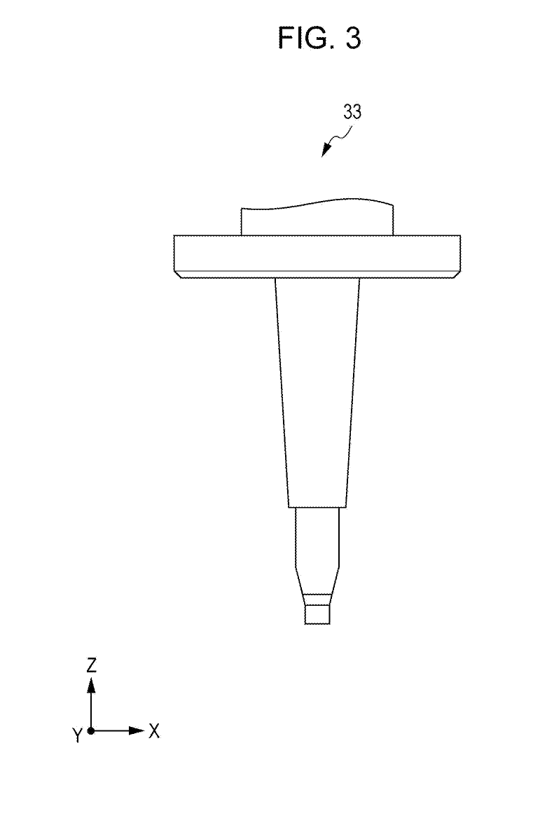

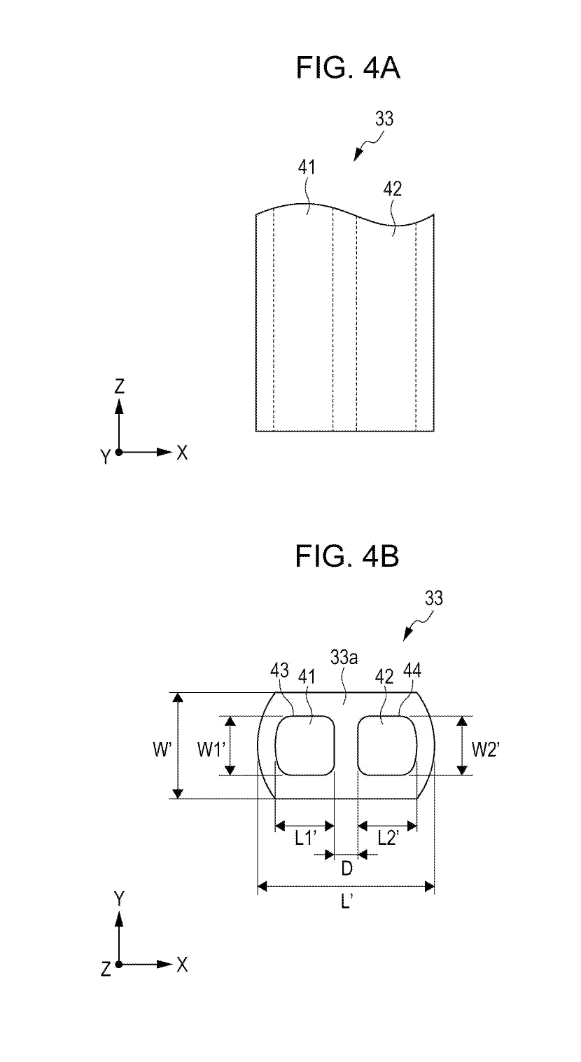

FIG. 3 is a side view showing the tip of the suction nozzle 33. FIGS. 4A and 4B are enlarged views showing the tip of the suction nozzle 33. FIG. 4A is a side view of the tip of the suction nozzle 33; FIG. 4B is a front view of the tip of the suction nozzle 33.

As shown in these drawings, the suction nozzle 33 has first and second suction holes 41, 42 extending in the vertical direction (along the Z axis). In the end face 33a of the tip (referred to hereinafter as tip end face 33a) of the suction nozzle 33, the areas in which the two suction holes 41, 42 open will be referred to hereinafter as the sucking areas. Thus, the suction nozzle 33 has first and second sucking areas 43 and 44 in the tip end face 33a.

The tip end face 33a of the suction nozzle 33 has a shape longer in one direction (along the X axis) and has the first and second sucking areas 43, 44 arranged side by side in the longitudinal direction (along the X axis) of the tip end face 33a.

FIGS. 5A and 5B show an exemplary electronic component 2A to be sucked and mounted by the suction nozzle 33. FIG. 5A is a side view of the electronic component 2A; FIG. 5B is a plan view of the electronic component 2A.

The electronic component 2A shown in FIGS. 5A and 5B is substantially parallelepiped in shape. The electronic component 2A has an electronic component body 2a, a first electrode 2b disposed on one side of the electronic component body 2a, and a second electrode 2c disposed on another side of the electronic component body 2a. Electronic components 2A having such a structure includes resistors, capacitors, and coils, for example.

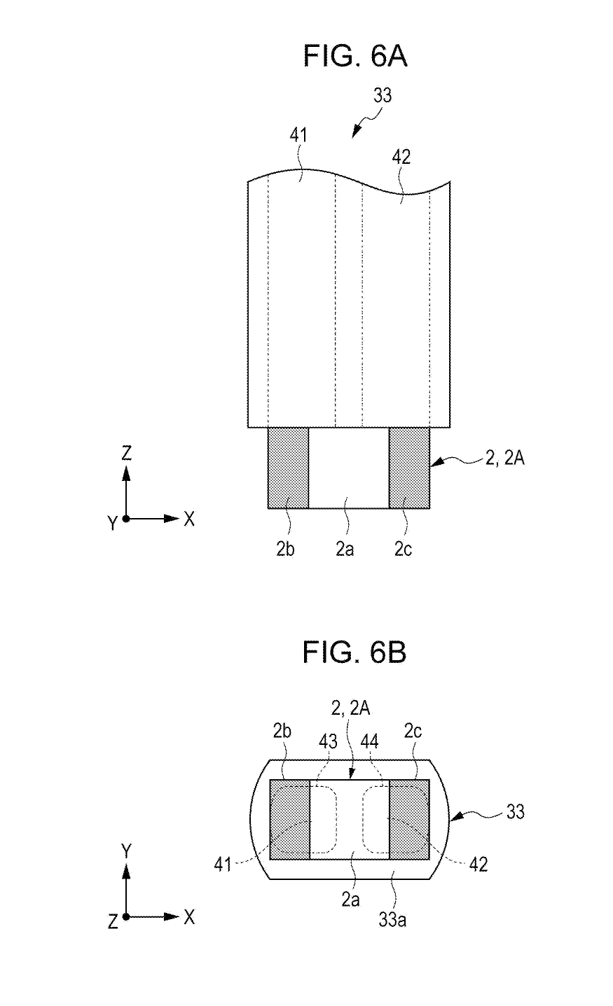

FIGS. 6A and 6B show the electronic component 2A sucked by the tip of the suction nozzle 33. FIG. 6A is a side view showing the sucked state of the electronic component 2A; FIG. 6B is a front view showing the sucked state of the electronic component 2A.

The first sucking area 43 of the suction nozzle 33 has an opening formed at the position corresponding to the first electrode 2b of the electronic component 2A. The second sucking area 44 of the suction nozzle 33 has an opening formed at the position corresponding to the second electrode 2c of the electronic component 2A. The first and second sucking areas 43, 44 are dimensioned such that the electronic component 2A is not sucked into the suction holes 41, 42.

The tip end face 33a and first and second sucking areas 43, 44 of the suction nozzle 33 are dimensioned so as to match in size to the electronic component 2A. Assuming here that the electronic component 2A is of type 0603 (0.6 mm×0.3 mm), exemplary sizes of the tip end face 33a and first and second sucking areas 43, 44 of the suction nozzle 33 will be explained below.

The length L (X axis direction), thickness T (Z axis direction), and width W (Y axis direction) of the electronic component 2A are 0.6 mm, 0.3 mm, and 0.3 mm, respectively. The length L1 (X axis direction) of the first electrode 2b and the length L2 (X axis direction) of the second electrode 2c are 0.15 mm, respectively.

In this case, the length L′ (X axis direction) and width W′ (Y axis direction) of the tip end face 33a of the electronic component 2A may be dimensioned to be 0.75 mm and 0.45 mm, respectively, for example. The length L1′, L2′ (X axis direction) of the first and second sucking areas 43, 44 may be dimensioned to be 0.25 mm, respectively, and the width W1′, W2′ (Y axis direction) of the first and second sucking areas 43, 44 may be dimensioned to be 0.25 mm, respectively, for example. The distance D between the first and second sucking areas 43, 44 may be dimensioned to be 0.1 mm, for example.

In this explanation, the electronic component 2A of type 0603 is adopted by way of example but the size of the electronic component 2A is not limited thereto. For example, the electronic component 2A may be of type 0402 (0.4 mm×0.2 mm) or type 1005 (10 mm×0.5 mm). Furthermore, the electronic component 2A may be larger in size than the type 1005. Even in this case, the first and second sucking areas 43, 44 of the suction nozzle 33 are formed at positions corresponding to the first and second electrodes 2b, 2c of the electronic component 2A.

Typically, a suction nozzle 33 matching in size to the electronic component 2A is used. For example, a suction nozzle 33 designed for 0603-type electronic components is used for the 0603-type electronic component 2A, while a suction nozzle 33 designed for 1005-type electronic components is used for the 1005-type electronic component 2A. The same holds true for both a variant of this embodiment and another embodiment described later.

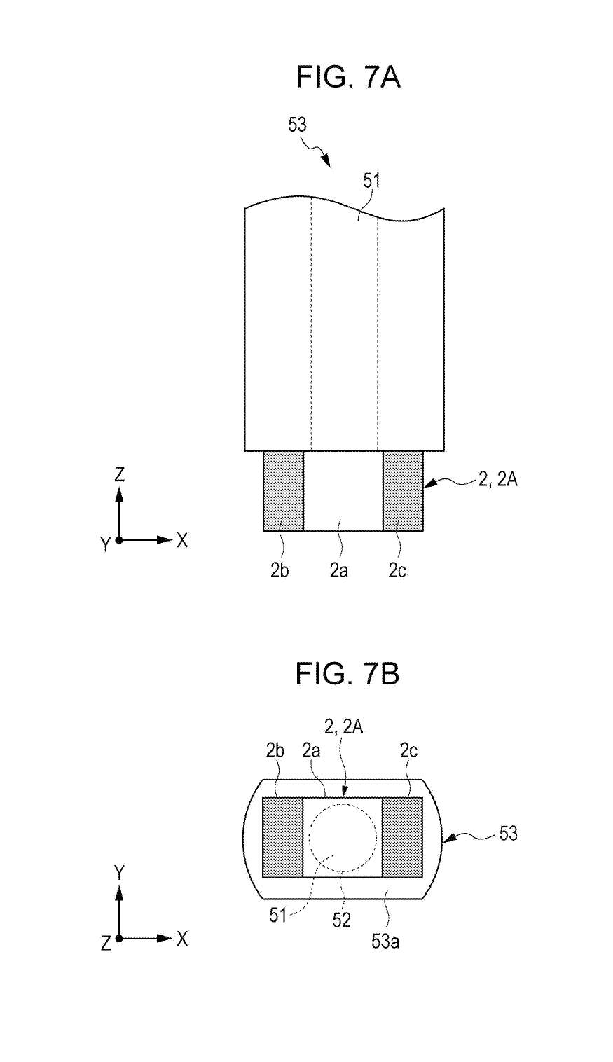

A case in which the electronic component 2A is sucked by the suction nozzle 53 according to a comparative example will now be described. FIGS. 7A and 7B show the electronic component 2A sucked by the suction nozzle 53 according to the comparative example. FIG. 7A is a side view of the sucked state of the electronic component 2A; FIG. 7B is a front view showing the sucked state of the electronic component 2A.

As shown in FIGS. 7A and 7B, the suction nozzle 53 according to the comparative example has a vertically (in the Z axis direction) extending suction hole 51 substantially at the center of the suction nozzle 53. A sucking area 52 is formed substantially at the center of the tip end face 53a of the suction nozzle 53. In the suction nozzle 53 according to the comparative example, the sucking area 52 is disposed at a position corresponding to the electronic component body 2a, off the first and second electrodes 2b, 2c. This causes a large area in the tip end face 53a of the suction nozzle 53 to be brought into contact with the first and second electrodes 2b, 2c of the electronic component 2A. When this suction nozzle 53 is repeatedly used to suck and mount electronic components 2A on the substrates 1, metal particles from the first and second electrodes 2b, 2c could be accumulated on the tip end face 53a of the suction nozzle 53.

On the other hand, the suction nozzle 33 according to the present embodiment has the first and second sucking areas 43, 44 formed at positions corresponding to the first and second electrodes 2b, 2c of the electronic component 2A as shown in FIGS. 6A and 6B. This allows a small area in the tip end face 33a of the suction nozzle 33 to be brought into contact with the first and second electrodes 2b, 2c. This can accordingly suppress the accumulation of metal particles from the first and second electrodes 2b, 2c on the tip end face 33a of the suction nozzle 33.

### [Description of Operations]

Operations of the mounting apparatus 100 according to the present embodiment will now be described.

A substrate 1 is first carried in by the conveyor 16 and positioned at a mounting position. Next, the head unit 35 is moved in the X-Y direction to the point of supply of an electronic component 2A (position of a supply window 91). Then, the suction nozzle 33 positioned at the operation position is moved to the position of the supply window 91 of a tape feeder 90 containing the electronic component 2A to be mounted. The suction nozzle 33 positioned at the operation position is lowered and is switched to a negative pressure by the air compressor. This causes the tip of the suction nozzle 33 to suck the electronic component 2A. Once the electronic component 2A has been sucked, the suction nozzle 33 having sucked the electronic component 2A is moved upward.

Next, the turret 32 is rotated to change the suction nozzle 33 positioned at the operation position. When another suction nozzle 33 is positioned at the operation position, this suction nozzle 33 is lowered to suck another electronic component 2A by the tip of the suction nozzle 33. In this manner, a plurality of electronic components 2A are sucked by the suction nozzles 33. When the head unit 35 is moved to the point of supply of electronic components 2A, all or some of the suction nozzles 33 may suck electronic components 2A.

With the first and second sucking areas 43, 44 formed at positions corresponding to the first and second electrodes 2b, 2c, the suction nozzle 33 according to the present embodiment can suck the electronic component 2A in a well-balanced manner with respect to the suction nozzle 33. When the electronic component 2A is not sucked in a correct position with the suction nozzle 33, the electronic component 2A can be repositioned automatically to the correct position with respect to the suction nozzle 33.

When the suction nozzle 33 is moved to the imaging position by the rotation of the turret 32, an image of the sucked state of the electronic component 2A is captured by the camera. For example, when the suction nozzle 33 is moved by the rotation of the turret 32 to the highest position (leftmost position in FIGS. 1 and 2), an image of the sucked state of the electronic component 2A is captured by the camera. As the turret 32 rotates, the suction nozzles 33 are positioned at the imaging position in turn and images of the sucked states of the electronic components 2A are captured of all the suction nozzles 33 having sucked the electronic components 2A. The images captured by the camera are subjected to image processing by the control unit and used to determine the sucked states.

The suction nozzle 53 according to the comparative example has a problem that metal particles from the electrodes are accumulated on the tip end face 53a of the suction nozzle 53, as described above. When the sucked state of the electronic component 2A with respect to the suction nozzle 53 is imaged and determined, the suction nozzle 53 not having sucked the electronic component 2A could be determined erroneously as having sucked the electronic component 2A. In addition, the boundary between the suction nozzle 53 and the electronic component 2A sucked by the suction nozzle 53 could be recognized erroneously.

On the other hand, in the present embodiment, with the first and second sucking areas 43, 44 formed at positions corresponding to the first and second electrodes 2b, 2c as described above, it is possible to suppress the accumulation of metal particles from the first and second electrodes 2b, 2c on the tip end face 33a of the suction nozzle 33. This can prevent the suction nozzle 33 not having sucked the electronic component 2A from being erroneously recognized as having sucked the electronic component 2A. This can also prevent erroneous recognition of the boundary between the suction nozzle 33 and the electronic component 2A sucked by the suction nozzle 33.

Once necessary electronic components 2A have been sucked by the suction nozzles 33, the head unit 35 is moved from the point of supply to a position above the substrate 1. Then, the suction nozzle 33 positioned at the operation position is aligned with a position on the substrate 1 on which the electronic component 2A is to be mounted. By the time this alignment operation is completed, the suction nozzle 33 is rotated around the axis thereof with respect to the turret 32 to adjust the orientation of the electronic component 2A sucked by the suction nozzle 33.

When the orientation of the electronic component 2A is adjusted, the orientation of the electronic component 2A is corrected on the basis of the information of the sucked state (sucked position) of the electronic component 2A with respect to the suction nozzle 33. Since the present embodiment can prevent the erroneous recognition of the boundary between the suction nozzle 33 and the electronic component 2A as described above, the orientation of the electronic component 2A can be corrected accurately.

Once the position of the suction nozzle 33 is aligned with the position on the substrate 1, the suction nozzle 33 is lowered. The air compressor then switches the suction nozzle 33 from the negative pressure to the positive pressure. With this, the electronic component 2A is released from the suction nozzle 33 and mounted on the substrate 1. In the present embodiment, the electronic component 2A can be accurately mounted on the substrate 1 because the orientation of the electronic component 2A has been accurately corrected on the basis of the information of the sucked state by the time the electronic component 2A is mounted.

Next, the turret 32 is rotated to change the suction nozzle 33 positioned at the operation position. When another suction nozzle 33 is positioned at the operation position, this suction nozzle 33 is lowered and the electronic component 2A sucked by the tip of the suction nozzle 33 is mounted on the substrate 1. Once all the electronic components 2A sucked by the suction nozzles 33 are mounted on the substrate 1, the head unit 35 is again moved from the position above the substrate 1 to the point of supply of electronic components 2A. After the mounting of electronic components 2A is completed, the substrate 1 is discharged by the conveyor 16.

The suction nozzle 53 according to the comparative example has a problem that metal particles from the electrodes are accumulated on the tip end face 53a of the suction nozzle 53 and the accumulated metal particles could adhere to the first and second electrodes 2b, 2c. This could make it difficult to release the electronic component 2A from the tip end face 53a of the suction nozzle 53 according to the comparative example when the air compressor switches the suction nozzle 53 from the negative pressure to the positive pressure to release the electronic component 2A.

On the other hand, the suction nozzle 33 according to the present embodiment can suppress the accumulation of metal particles from the first and second electrodes 2b, 2c on the tip end face 33a of the suction nozzle 33. The tip end face 33a of the suction nozzle 33 can thus be prevented from adhering to the first and second electrodes 2b, 2c. The suction nozzle 33 according to the present embodiment can therefore smoothly release the electronic component 2A when the electronic component 2A is to be released from the suction nozzle 33.

### [Variant of This Embodiment]

In the above example, the electronic component 2A described as the exemplary electronic component 2 to be sucked and mounted by the suction nozzle 33 has the electronic component body 2a having substantially the same thickness as the first and second electrodes 2b, 2c. Some electronic components 2 may have an electronic component body 2a thinner than the first and second electrodes 2b, 2c. For example, capacitors often have an electronic component body 2a thinner than the first and second electrodes 2b, 2c.

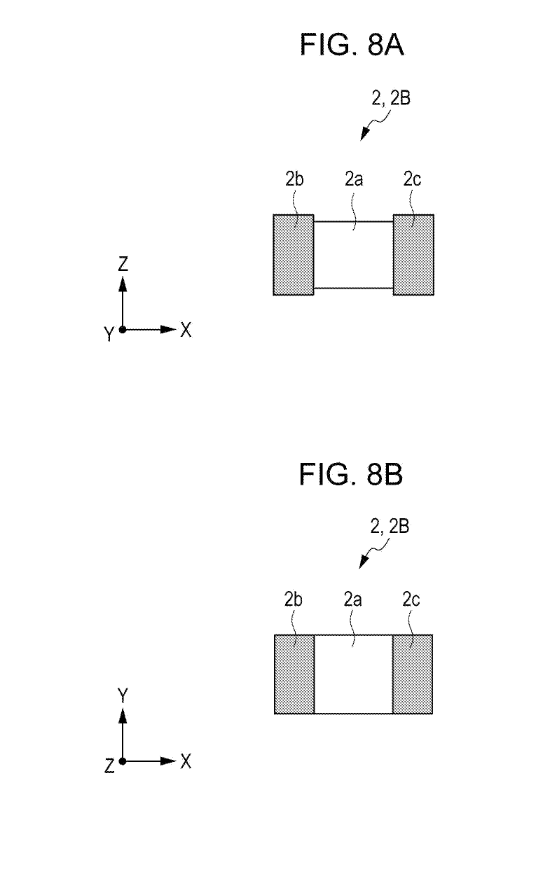

FIGS. 8A and 8B show an exemplary electronic component 2B having an electronic component body 2a thinner than the first and second electrodes 2b, 2c. FIG. 8A is a side view of the electronic component 2B; FIG. 8B is a plan view of the electronic component 2B.

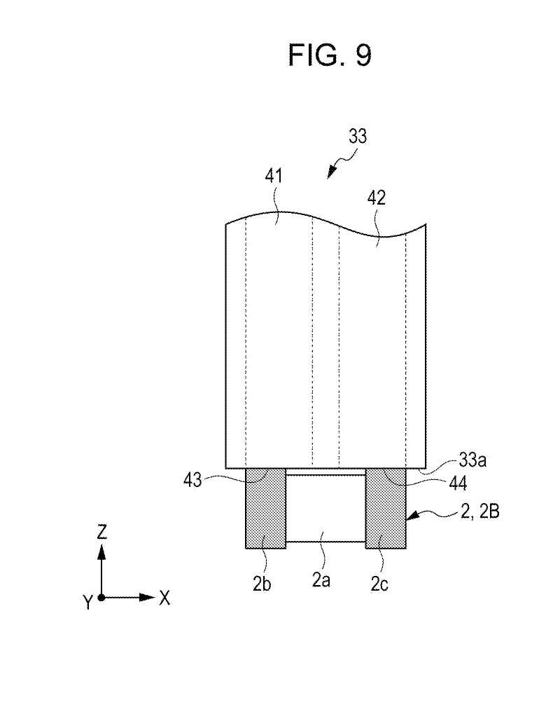

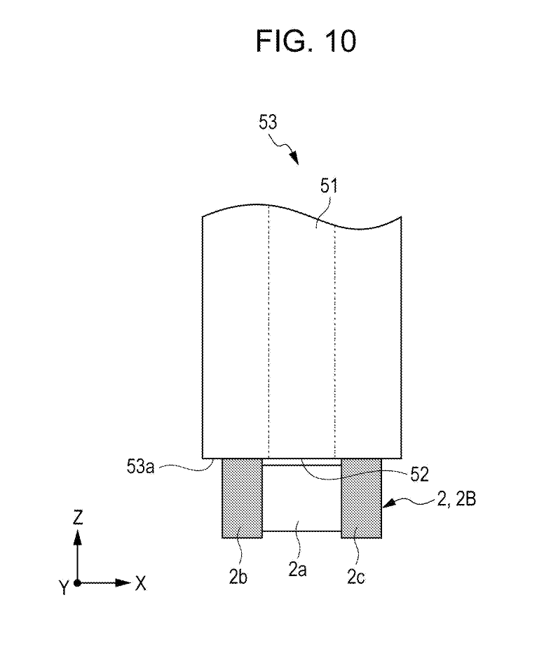

FIG. 9 is a side view showing the electronic component 2B shown in FIGS. 8A and 8B sucked by the suction nozzle 33 according to the present embodiment. FIG. 10 is a side view showing the electronic component 2B shown in FIGS. 8A and 8B sucked by the suction nozzle 53 according to the comparative example.

As shown in FIG. 10, when the electronic component 2B is sucked by the suction nozzle 53 according to the comparative example, a gap is left between the sucking area 52 and the electronic component body 2a directly below the sucking area 52. When the suction nozzle 53 sucks and holds the electronic component 2B, air leakage occurs through this gap and reduces the suction force of the suction nozzle 53 according to the comparative example. Air leakage also occurs when the compressor switches the suction nozzle 53 from the negative pressure to the positive pressure to release the electronic component 2B, making it difficult to release the electronic component 2B from the suction nozzle 53. It is especially difficult to release the electronic component 2B from the suction nozzle 53 according to the comparative example, because the suction nozzle 53 tends to adhere to the electrodes 2b, 2c due to the accumulation of metal particles as described above.

On the other hand, in the suction nozzle 33 according to the present embodiment, the first and second sucking areas 43, 44 are formed at positions corresponding to the first and second electrodes 2b, 2c of the electronic component 2B as shown in FIG. 9. No gap is left between the first and second sucking areas 43, 44 and the first and second electrodes 2b, 2c located directly below the first and second sucking areas 43, 44. This can suppress air leakage and allows the suction nozzle 33 according to the present embodiment to securely hold the electronic component 2B with a strong suction force. Since the air leakage can be suppressed in the present embodiment, the electronic component 2B can be released smoothly from the suction nozzle 33 when the electronic component 2B is to be released from the suction nozzle 33.

As described above, the suction nozzle 33 according to the present embodiment can mitigate air leakage and other related problems and is especially effective to suck the electronic component 2B having the electronic component body 2a thinner than the first and second electrodes 2b, 2c.

### Another Embodiment

Another embodiment of the present application will now be described. In the description below, the members having the same structures and functions as those in the above embodiment will be denoted with the same reference characters and description thereof will be omitted or simplified.

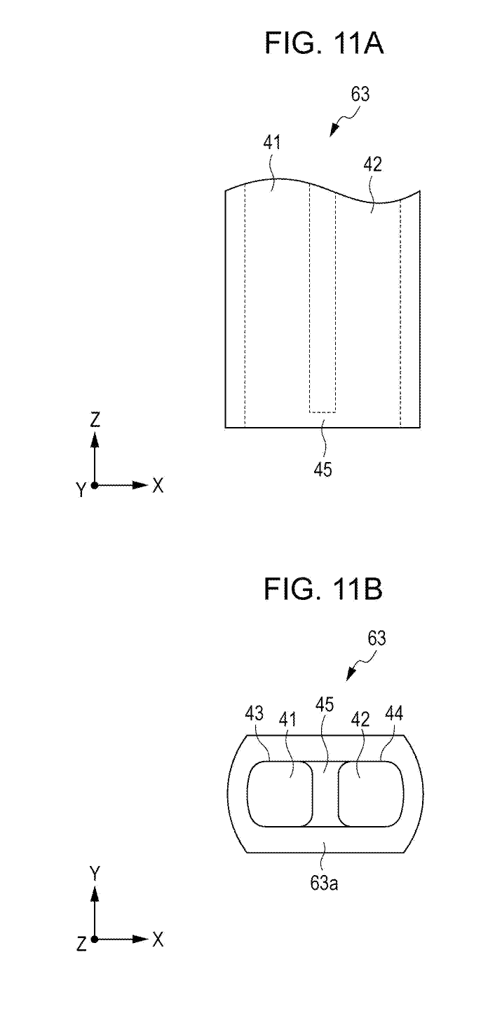

FIGS. 11A and 11B show the tip of the suction nozzle 63 according to the present embodiment. FIG. 11A is a side view of the tip of the suction nozzle 63; FIG. 11B is a front view of the tip of the suction nozzle 63.

As shown in FIGS. 11A and 11B, the suction nozzle 63 according to the present embodiment has a recess formed between the first and second sucking areas 43, 44. This area having the recess formed therein will be referred to hereinafter as the recessed area 45. The other portions of the suction nozzle 63 are similar in structure to those of the suction nozzle 33 described in the above embodiment.

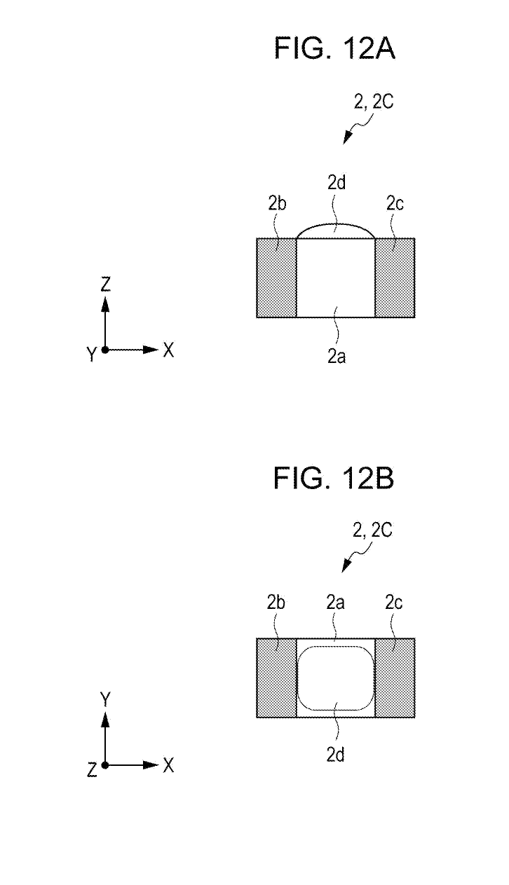

FIGS. 12A and 12B show an exemplary electronic component 2C to be sucked and mounted by the suction nozzle 63 according to the present embodiment. FIG. 12A is a side view of the electronic component 2C; FIG. 12B is a plan view of the electronic component 2C.

As shown in FIGS. 12A and 12B, the electronic component 2C has an electronic component body 2a, a first electrode 2b disposed on one side of the electronic component body 2a, and a second electrode 2c disposed on another side of the electronic component body 2a. The electronic component 2C also has a projection 2d on the electronic component body 2a, between the first and second electrodes 2b, 2c.

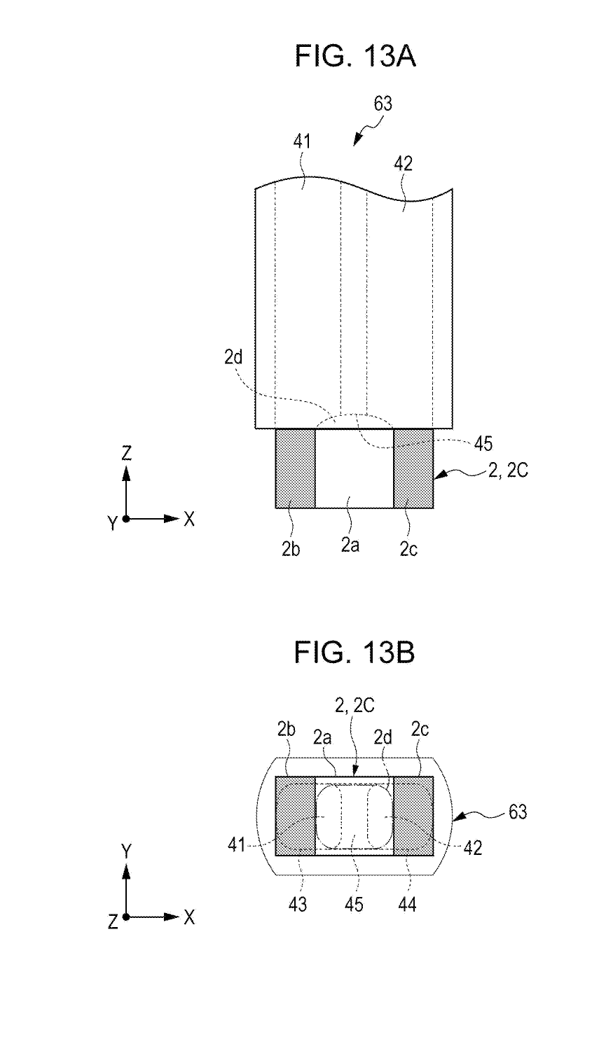

FIGS. 13A and 13B show the electronic component 2C sucked by the suction nozzle 63. FIG. 13A is a side view showing the sucked state of the electronic component 2C; FIG. 13B is a front view showing the sucked state of the electronic component 2C.

As shown in FIG. 13A, the recessed area 45 of the suction nozzle 63 is formed so as to fit over the projection 2d of the electronic component 2C. When the electronic component 2C is sucked and held by the suction nozzle 63, the projection 2d of the electronic component 2C fits in the recessed area 45 of the suction nozzle 63. Since the projection 2d of the electronic component 2C fits in the recessed area 45 of the suction nozzle 63 in this manner, the present embodiment can prevent the rotation of the electronic component 2C with respect to the suction nozzle 63.

When the electronic component 2C shown in FIGS. 12A and 12B is sucked by a suction nozzle without the recessed area 45, the projection 2d of the electronic component 2C would be brought into point-contact with the area between the first and second sucking areas 43, 44 and the electronic component 2C could rotate with respect to the suction nozzle.

### [Variant of This Embodiment]

In the above description, the suction nozzle 63(33) matching in size to the electronic component 2 is used. For example, the suction nozzle 63(33) designed for type 0402 is used for the 0402-type electronic component 2; the suction nozzle 63(33) designed for type 0603 is used for the 0603-type electronic component 2.

On the other hand, the suction nozzle 63 shown in FIGS. 11A and 11B can be used to suck and mount electronic components 2 of unmatched sizes. This will be described below.

An electronic component 2 having electrodes disposed at positions corresponding to the first and second sucking areas 43, 44 of the suction nozzle 63(33) will be referred to hereinafter as the first electronic component 2(2A-2C) and an electronic component 2 larger in size than the first electronic component 2(2A-2C) will be referred to as the second electronic component 2D. For example, for the suction nozzle 63(33) designed for type 0603, the 0603-type electronic component 2 is the first electronic component 2(2A-2C) and the 1005-type electronic component 2 is the second electronic component 2D.

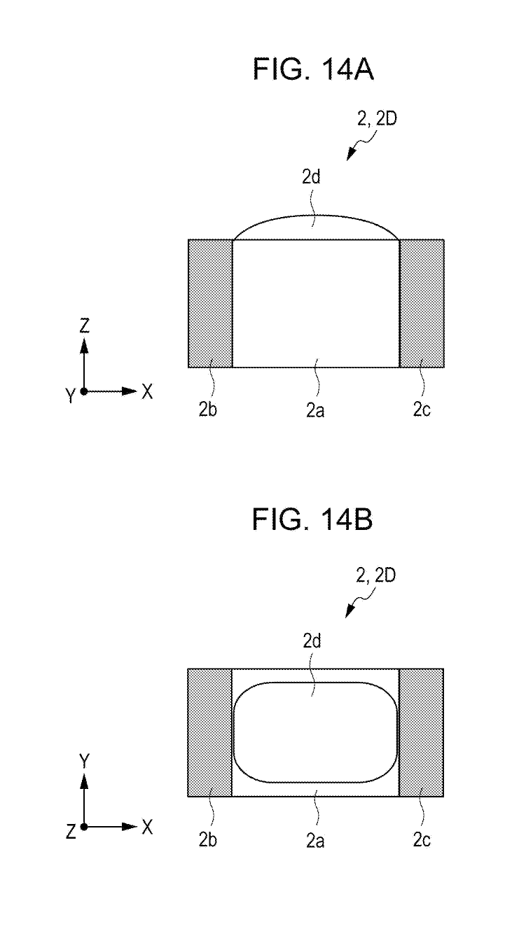

FIGS. 14A and 14B show an exemplary second electronic component 2D. As shown in FIGS. 14A and 14B, the second electronic component 2D has an electronic component body 2a, a first electrode 2b disposed on one side of the electronic component body 2a, and a second electrode 2c disposed on another side of the electronic component body 2a. The electronic component 2D also has a projection 2d on the electronic component body 2a, between the first and second electrodes 2b, 2c.

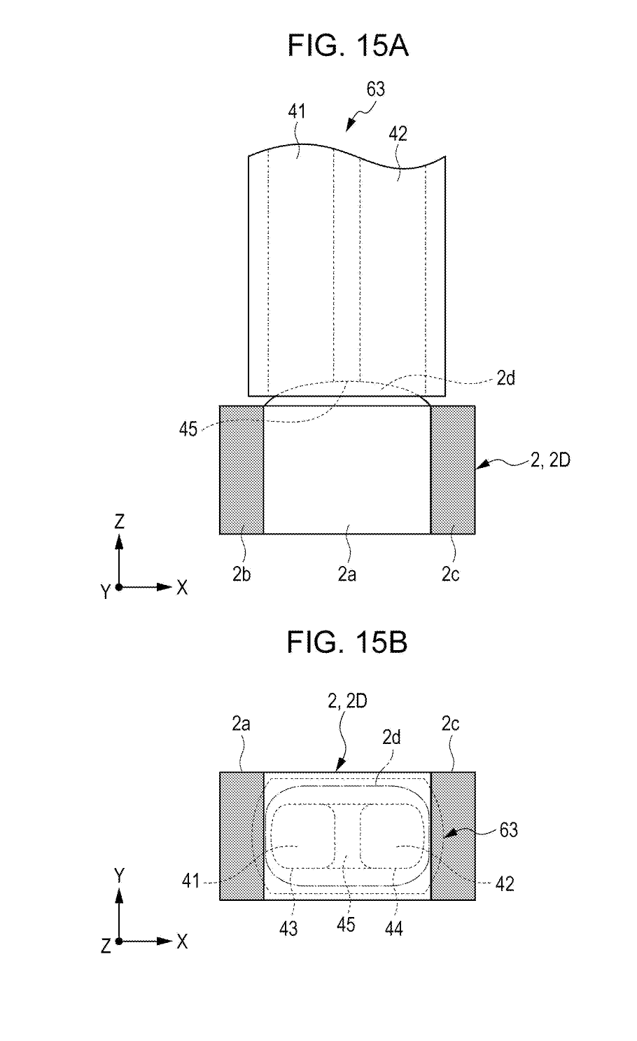

FIGS. 15A and 15B show the second electronic component 2D sucked by the tip of the suction nozzle 63. FIG. 15A is a side view showing the sucked state of the second electronic component 2D; FIG. 15B is a front view showing the sucked state of the second electronic component 2D.

As shown in FIGS. 15A and 15B, a total area formed of the first and second sucking areas 43, 44 and recessed area 45 of the suction nozzle 63 receives the projection 2d of the second electronic component 2D. When the second electronic component 2D is sucked and held by the suction nozzle 63, the projection 2d of the second electronic component 2D fits in the total area formed of the first and second sucking areas 43, 44 and recessed area 45 of the suction nozzle 63, as shown in FIG. 15A.

The suction nozzle 63 can thus suck and mount not only the first electronic component 2(2A-2C) matching in size to the suction nozzle 63 but also the second electronic component 2D larger than the matching size. This means that the suction nozzle 63 can be used commonly to mount the first electronic component 2(2A-2C) and to mount the second electronic component 2D. The second electronic component 2D can also be prevented from rotating with respect to the suction nozzle 63, because the projection 2d of the second electronic component 2D fits in the total area formed of the first and second sucking areas 43, 44 and recessed area 45 of the suction nozzle 63.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A suction nozzle sucking a first electronic component that is mounted on a substrate and has first and second electrodes, the suction nozzle comprising:
a first sucking area with an opening formed in an area corresponding to the first electrode; and
a second sucking area with an opening formed in an area corresponding to the second electrode.

2. The suction nozzle according to claim 1, further comprising:
a recessed area formed between the first and second sucking areas.

3. The suction nozzle according to claim 2,
wherein the first electronic component has a projection provided between the first and second electrodes,
wherein the recessed area has a recess formed in an area corresponding to the projection.

4. The suction nozzle according to claim 2,
wherein the suction nozzle is used commonly to mount the first electronic component and to mount a second electronic component having a projection and larger in size than the first electronic component,
wherein a total area formed of the first and second sucking areas and the recessed area receives the projection of the second electronic component.

5. The suction nozzle according to claim 1,
wherein the first electronic component has the first electrode disposed at one end thereof, the second electrode disposed at another end thereof, and an electronic component body thinner than the first and second electrodes.

6. A mounting apparatus comprising:
a head; and
a suction nozzle adapted to be attached to the head and adapted to suck an electronic component that is mounted on a substrate and has first and second electrodes, the suction nozzle having a first sucking area with an opening formed in an area corresponding to the first electrode and a second sucking area with an opening formed in an area corresponding to the second electrode.

7. A method for mounting an electronic component having first and second electrodes, the method comprising:
sucking the electronic component using a suction nozzle having a first sucking area with an opening formed in an area corresponding to the first electrode and a second sucking area with an opening formed in an area corresponding to the second electrode; and
moving the suction nozzle having sucked the electronic component to a position above the substrate and mounting the electronic component on the substrate.

8. A method for manufacturing a component-mounted substrate, the method comprising:
sucking an electronic component having first and second electrodes using a suction nozzle having a first sucking area with an opening formed in an area corresponding to the first electrode and a second sucking area with an opening formed in an area corresponding to the second electrode; and
moving the suction nozzle having sucked the electronic component to a position above a substrate and mounting the electronic component on the substrate.
